(19) United States
(12) Patent Application Publication
(10) Pub. No.: US 2013/0260665 A1
(43) Pub. Date: Oct. 3, 2013

(54) AIR DAM MODULE AND ELECTRONIC DEVICE HAVING THE SAME

(71) Applicant: ZHENG-HENG SUN, Tu-Cheng (TW)

(72) Inventor: ZHENG-HENG SUN, Tu-Cheng (TW)

(73) Assignee: HON HAI PRECISION INDUSTRY CO., LTD., Tu-Cheng (TW)

(21) Appl. No.: 13/564,740

(22) Filed: Aug. 2, 2012

(30) Foreign Application Priority Data
Mar. 28, 2012 (CN) 201210085973.0

(51) Int. Cl. H05K 5/02; F24F 7/007

(52) U.S. Cl. 454/184

(57) ABSTRACT

An electronic device includes an air dam module. The air dam module includes a frame, a first rotating member, and a second rotating member. The frame defines a vent. The first rotating member is rotatably received in the vent, to vertically block a lower half of the vent by due to gravity. The second rotating member is rotatably received in the vent, to vertically block an upper half of the vent by due to gravity.

### BACKGROUND

1. Technical Field

The present disclosure relates to an electronic device including an air dam module.

2. Description of Related Art

Fans are mounted in an electronic device for dissipating heat from electronic components in the electronic device. However, when a fan is broken, air pressure in the electronic device changes, which will cause air to back flow and turbulence, adversely affecting heat dissipation from the electronic device.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, assembled, isometric view of a first embodiment of an electronic device mountable with two air dam modules.

FIG. 2 is an exploded, isometric view of one of the air dam modules of FIG. 1.

FIGS. 3 and 4 are assembled, isometric views of the air dam module of FIG. 2 from different perspectives, and in different states.

FIGS. 5 and 6 are assembled, isometric views of a second embodiment of an air dam module in different states.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean “at least one”.

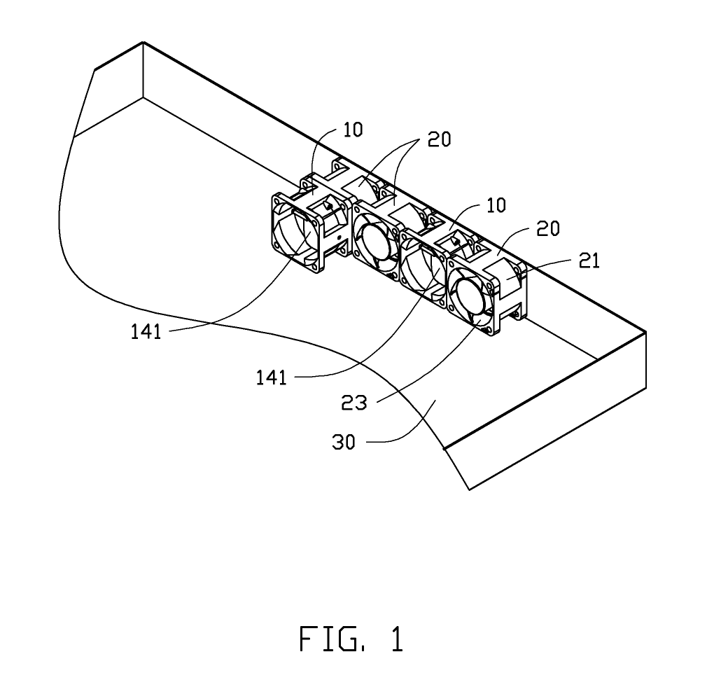

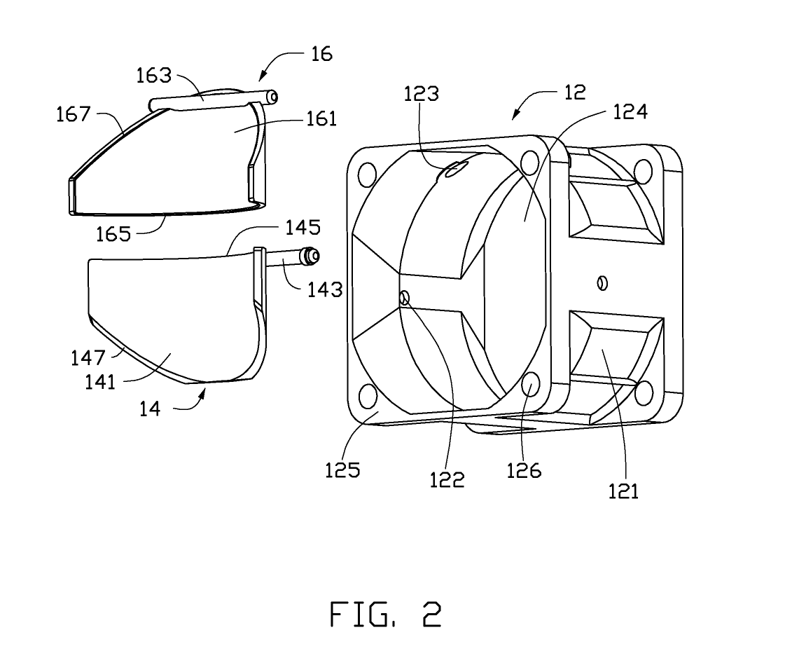

As shown in FIGS. 1 and 2, an electronic device according to a first embodiment of the present disclosure includes a chassis 30, a plurality of standard fans 20, and two air dam modules 10.

Each standard fan 20 includes a first frame 21 defining a first vent 23 having a substantially circular cross section.

Each air dam module 10 includes a second frame 12, a first rotating member 14, and a second rotating member 16.

The second frame 12 has the same shape and size as the first frame 21 of each standard fan 20. The second frame 12 includes a columnar main body 121, and two fixing plates 125 at front and rear ends of the main body 121. A second vent 124 having a substantially circular cross section is axially defined in the main body 121, extending through the fixing plates 125. A cross-sectional area of the second vent 124 is equal to a cross-sectional area of the first vent 23 of each standard fan 20. A fixing hole 126 is defined in each corner of each fixing plate 125. Therefore, the second frame 12 has the same manner of mounting as the standard fan 20. Middles of opposite sides of the main body 121 each define a first pivot hole 122 communicating with the second vent 124. Tops of the opposite sides of the main body 121 each define a second pivot hole 123 communicating with the second vent 124. The first and second pivot holes 122 and 123 are arranged on a same vertical plane.

The first rotating member 14 includes an arc-shaped first shield plate 141 and a first pivot 143. Opposite ends of the first shield plate 141 are bent backwards. A top side 145 of the first shield plate 141 is arranged on a horizontal plane, and the first pivot 143 is connected to a middle of the top side 145. Opposite ends of the first pivot 143 protrude out of the opposite ends of the first shield plate 141. A bottom side 147 of the first shield plate 141 is arc-shaped, with a middle of the bottom side 147 protruding downward. A perpendicular distance between the first pivot 143 and the middle of the bottom side 147 is not more than a perpendicular distance between the first pivot holes 122 and the front end of the second frame 12.

The second rotating member 16 includes an arc-shaped second shield plate 161 and a second pivot 163. Opposite ends of the second shield plate 161 are bent backwards. A top side 167 of the second shield plate 161 is arc-shaped, with a middle of the top side 167 protruding upward. The second pivot 163 is connected to the middle of the top side 167, and opposite ends of the second pivot 163 protrude out of the opposite ends of the second shield plate 161. A bottom side 165 of the second shield plate 161 is arranged on a horizontal plane. A perpendicular distance between the second pivot 163 and the bottom side 165 is not more than a perpendicular distance between the second pivot holes 123 and the front end of the second frame 12.

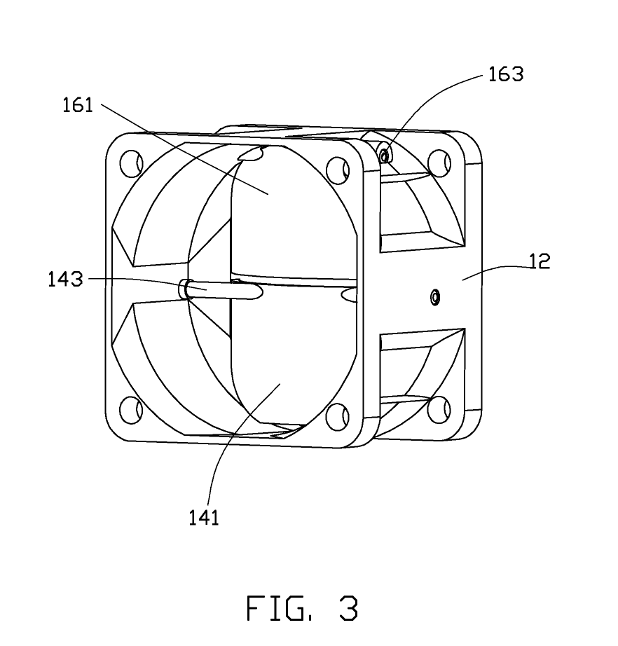

As shown in FIG. 3, to assemble one air dam module 10, the first pivot 143 is deformed to be received in the second vent 124, to allow the opposite ends of the first pivot 143 to align with the first pivot holes 122. The first pivot 143 is restored, to allow the opposite ends of the first pivot 143 to rotatably engage in the first pivot holes 122. Thereby, the first rotating member 14 is rotatably received and held captive in the second vent 124. The first shield plate 141 hangs vertically under the first pivot 143 by gravity, and blocks the lower half of the second vent 124. The opposite ends and the bottom side 147 of the first shield plate 141 abut inner surfaces of the opposite sides and the bottom side of the lower half of the main body 121.

The second pivot 163 is deformed to be received in the second vent 124, to allow the opposite ends of the second pivot 163 to align with the second pivot holes 123. The second pivot 163 is restored, to allow the opposite ends of the second pivot 163 to rotatably engage in the second pivot holes 123. Thereby, the second rotating member 16 is rotatably received and held captive in the second vent 124. The second shield plate 161 hangs vertically under the second pivot 163 by gravity, and blocks the upper half of the second vent 124. The opposite ends and the top side 167 of the second shield plate 161 abut inner surfaces of the opposite sides and the top side of the upper half of the main body 121. The bottom side 165 of the second shield plate 161 is adjacent to the top side 145 of the first shield plate 141.

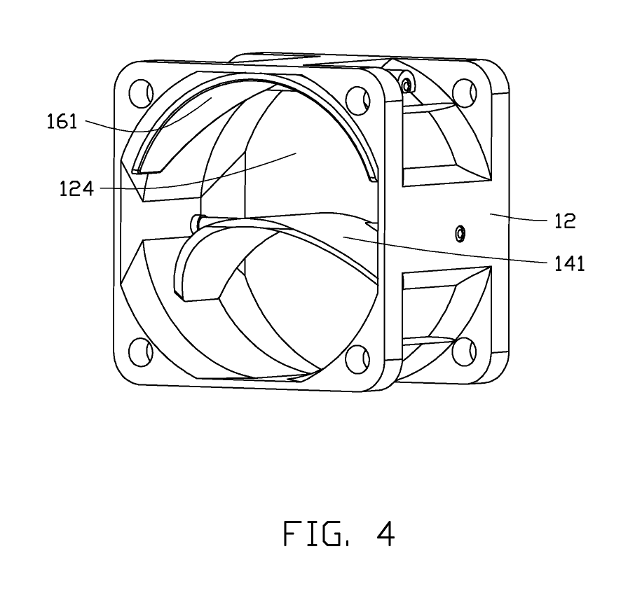

As shown in FIG. 4, when an airflow from a standard fan 20 behind the air dam module 10 is blown forward towards the air dam module 10, the first and second rotating members 14 and 16 rotate forward 90 degrees around the first and second pivot holes 122 and 123. The first and second shield plates 141 and 161 are completely received in the second vent 124 all the time, and will never extend out of the second frame 12 to take up outside space.

As shown in FIG. 1, before a replacement for a broken standard fan 20 in the chassis 30 can be fitted, an air dam module 10 can replace the broken down standard fan 20 to be mounted in the chassis 30. The first and second rotating members 14 and 16 are vertical by means of gravity, and so block the second vent 124. Air pressure at the air dam module 10 will not change substantially, so the first and second rotating members 14 and 16 can prevent air back flowing towards the air dam module 10.

If there is enough space in the chassis 30, an air dam module 10 can be mounted to a front end of a standard fan 20. When the standard fan 20 operates, the first and second rotating members 14 and 16 are blown by the standard fan 20 to rotate 90 degrees, to allow the airflow produced by the standard fan 20 to pass through the second vent 124. When the standard fan 20 is broken-down, the first and second rotating members 14 and 16 are vertically arranged in the air dam module 10 by gravity, and block the second vent 124, which will prevent air back flowing towards the air dam module 10.

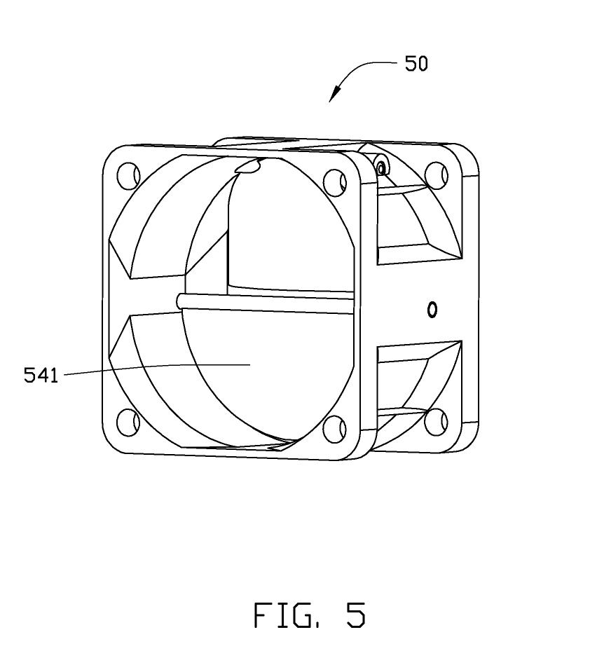

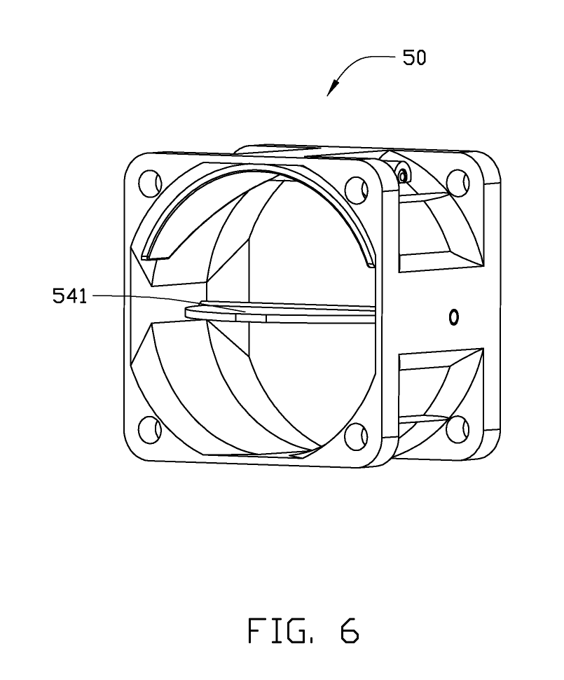

FIGS. 5 and 6 show an air dam module 50 according to a second embodiment of the present disclosure. Compared with the air dam module 10, the air dam module 50 replaces the arc-shaped first shield plate 141 to a flat semicircular first shield plate 541. A bottom side of the first shield plate 541 is arc-shaped, with a middle of the bottom side protruding downward.

Even though numerous characteristics and advantages of the embodiments have been set forth in the foregoing description, together with details of the structure and the functions of the embodiments, the disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. An air dam module, comprising:
a frame defining a vent through a front end and a rear end of the frame, the vent defining a substantially circular cross section;
a first rotating member received in the vent, wherein a top side of the first rotating member is rotatably connected to the frame, the first rotating member comprises a first shield plate forming an arc-shaped bottom side with a middle of the bottom side protruding downward, the first shield plate vertically blocks a lower half of the vent by its gravity upon a condition that its gravity is not overcome by an airflow passing through the vent; and
a second rotating member received in the vent, wherein a top side of the second rotating member is rotatably connected to the frame, the second rotating member comprises an arc-shaped second shield plate, opposite ends of the second shield plate are bent backwards, a top side of the second shield plate is arc-shaped, with a middle of the top side protruding upward, the second shield plate vertically blocks an upper half of the vent by its gravity upon a condition that its gravity is not overcome by an airflow passing through the vent.

2. The air dam module of claim 1, wherein the bottom side and two opposite ends of the first shield plate abut portions of the frame bounding the lower half of the vent, the top side and opposite ends of the second shield plate abut portions of the frame bounding the upper half of the vent, in response to the first and second rotating members vertically blocking the vent.

3. The air dam module of claim 2, wherein a top side of the first shield plate is arranged on a horizontal plane, a bottom side of the second shield plate is arranged on a horizontal plane and adjacent to the top side of the first shield plate, in response to the first and second rotating members vertically blocking the vent.

4. The air dam module of claim 3, wherein the first shield plate is arc-shaped, and opposite ends of the first shield plate are bent backwards.

5. The air dam module of claim 3, wherein the first shield plate is flat, and is substantially semicircular shaped.

6. The air dam module of claim 3, wherein the first rotating member further comprises a first pivot connected to the top side of the first shield plate, middles of opposite sides of the frame each define a first pivot hole communicating with the vent, opposite ends of the first pivot are rotatably engaged in the first pivot holes.

7. The air dam module of claim 6, wherein the second rotating member further comprises a second pivot connected to the top side of the second shield plate, tops of opposite sides of the frame each define a second pivot hole communicating with the vent, opposite ends of the second pivot are rotatably engaged in the second pivot holes.

8. The air dam module of claim 7, wherein a perpendicular distance between the first pivot and the middle of the bottom side of the first shield plate is not more than a perpendicular distance between the first pivot holes and the front end of the frame, a perpendicular distance between the second pivot and the bottom side of the second shield plate is not more than a perpendicular distance between the second pivot holes and the front end of the frame.

9. An electronic device, comprising:
a chassis; and
an air dam module comprising a frame mounted to the chassis and defining a substantially circular vent through a front end and a rear end of the frame, wherein the frame has the same shape and size as a standard fan, the air dam module further comprises:
a first rotating member received in the vent, wherein a top side of the first rotating member is rotatably connected to the frame, the first rotating member comprises a first shield plate forming an arc-shaped bottom side with a middle of the bottom side protruding downward, the first shield plate vertically blocks a lower half of the vent by its gravity upon a condition that its gravity is not overcome by an airflow passing through the vent; and
a second rotating member received in the vent, wherein a top side of the second rotating member is rotatably connected to the frame, the second rotating member comprises an arc-shaped second shield plate, opposite ends of the second shield plate are bent backwards, a top side of the second shield plate is arc-shaped, with a middle of the top side protruding upward, the second shield plate vertically blocks an upper half of the vent by its gravity upon a condition that its gravity is not overcome by an airflow passing through the vent.

10. The electronic device of claim 9, wherein the bottom side and two opposite ends of the first shield plate abut portions of the frame bounding the lower half of the vent, the top side and opposite ends of the second shield plate abut portions of the frame bounding the upper half of the vent, a top side of the first shield plate is arranged on a horizontal plane, a bottom side of the second shield plate is arranged on a horizontal plane and adjacent to the top side of the first shield plate, in response to the first and second rotating members vertically blocking the vent.

11. The electronic device of claim 10, wherein the first shield plate is arc-shaped, and opposite ends of the first shield plate are bent backwards.

12. The electronic device of claim 10, wherein the first shield plate is flat, and is substantially semicircular shaped.

13. The electronic device of claim 10, wherein the first rotating member further comprises a first pivot connected to the top side of the first shield plate, middles of opposite sides of the frame each define a first pivot hole communicating with the vent, opposite ends of the first pivot are rotatably engaged in the first pivot holes, the second rotating member further comprises a second pivot connected to the top side of the second shield plate, tops of opposite sides of the frame each define a second pivot hole communicating with the vent, opposite ends of the second pivot are rotatably engaged in the second pivot holes.

14. The electronic device of claim 13, wherein a perpendicular distance between the first pivot and the middle of the bottom side of the first shield plate is not more than a perpendicular distance between the first pivot holes and the front end of the frame, a perpendicular distance between the second pivot and the bottom side of the second shield plate is not more than a perpendicular distance between the second pivot holes and the front end of the frame.

15. An electronic device, comprising:
a chassis;
a standard fan mounted in the chassis and comprising a first frame, the first frame defining a first vent through a front end and a rear end of the first frame; and
an air dam module mounted to the front end of the first frame, the air dam module comprising a second frame defining a second vent aligning with the first vent, wherein the second frame has the same shape and size as the first frame, the air dam module further comprises:
a first rotating member received in the vent, wherein a top side of the first rotating member is rotatably connected to the frame, the first rotating member comprises a first shield plate forming an arc-shaped bottom side with a middle of the bottom side protruding downward, the first shield plate vertically blocks a lower half of the vent by its gravity upon a condition that its gravity is not overcome by an airflow passing through the vent; and
a second rotating member received in the vent, wherein a top side of the second rotating member is rotatably connected to the frame, the second rotating member comprises an arc-shaped second shield plate, opposite ends of the second shield plate are bent backwards, a top side of the second shield plate is arc-shaped, with a middle of the top side protruding upward, the second shield plate vertically blocks an upper half of the vent by its gravity upon a condition that its gravity is not overcome by an airflow passing through the vent, the first and second rotating members rotate forward 90 degrees, in response to the standard fan blowing air towards the air dam module.

16. The electronic device of claim 15, wherein the bottom side and two opposite ends of the first shield plate abut portions of the frame bounding the lower half of the vent, the top side and opposite ends of the second shield plate abut portions of the frame bounding the upper half of the vent, a top side of the first shield plate is arranged on a horizontal plane, a bottom side of the second shield plate is arranged on a horizontal plane and adjacent to the top side of the first shield plate, in response to the first and second rotating members vertically blocking the vent.

17. The electronic device of claim 17, wherein the first shield plate is arc-shaped, and opposite ends of the first shield plate are bent backwards.

18. The electronic device of claim 17, wherein the first shield plate is flat, and is substantially semicircular shaped.

19. The electronic device of claim 17, wherein the first rotating member further comprises a first pivot connected to the top side of the first shield plate, middles of opposite sides of the frame each define a first pivot hole communicating with the vent, opposite ends of the first pivot are rotatably engaged in the first pivot holes, the second rotating member further comprises a second pivot connected to the top side of the second shield plate, tops of opposite sides of the frame each define a second pivot hole communicating with the vent, opposite ends of the second pivot are rotatably engaged in the second pivot holes.

20. The electronic device of claim 19, wherein a perpendicular distance between the first pivot and the middle of the bottom side of the first shield plate is not more than a perpendicular distance between the first pivot holes and a front end of the frame, a perpendicular distance between the second pivot and the bottom side of the second shield plate is not more than a perpendicular distance between the second pivot holes and the front end of the frame.
